(19) United States
(12) Patent Application Publication
(10) Pub. No.: US 2025/0098240 A1
(43) Pub. Date: Mar. 20, 2025

(54) DIELECTRIC AND TWO-DIMENSIONAL SEMICONDUCTOR MATERIAL NANOSHEET DEVICES

(71) Applicant: International Business Machines Corporation, Armonk, NY (US)

(72) Inventors: Huimei Zhou, Albany, NY (US); Nicolas Jean Loubet, Guilderland, NY (US); Ruilong Xie, Niskayuna, NY (US); Miaomiao Wang, Albany, NY (US)

(21) Appl. No.: 18/468,279

(22) Filed: Sep. 15, 2023

(51) Int. Cl. H01L 29/06; H01L 29/423; H01L 29/66; H01L 29/775; H01L 29/786

(52) U.S. Cl. CPC H10D 62/121; H10D 30/014; H10D 30/43; H10D 30/6735; H10D 30/6757; H10D 64/017; H10D 64/018; H10D 64/021

(57) ABSTRACT

A semiconductor device comprises a stacked structure comprising a plurality of gate structures alternately stacked with a plurality of dielectric layers. Respective ones of the plurality of gate structures comprise a gate region and a gate dielectric layer disposed around the gate region. Respective ones of the plurality of dielectric layers are disposed between a first two-dimensional semiconductor material layer of a plurality of two-dimensional semiconductor material layers and a second two-dimensional semiconductor material layer of the plurality of two-dimensional semiconductor material layers. The gate dielectric layer of the respective ones of the plurality of gate structures contacts at least one of the plurality of two-dimensional semiconductor material layers.

### BACKGROUND

The present application relates to semiconductors, and more specifically, to techniques for forming semiconductor structures. Semiconductors and integrated circuit chips have become ubiquitous within many products, particularly as they continue to decrease in cost and size. There is a continued desire to reduce the size of structural features and/or to provide a greater amount of structural features for a given chip size. Miniaturization, in general, allows for increased performance at lower power levels and lower cost. Present technology is at or approaching atomic level scaling of certain micro-devices such as logic gates, field-effect transistors (FETs), and capacitors.

### SUMMARY

Embodiments of the invention provide techniques for forming dielectric and two-dimensional (2D) semiconductor material layers for nanosheet devices.

In one embodiment, a semiconductor device comprises a stacked structure comprising a plurality of gate structures alternately stacked with a plurality of dielectric layers. Respective ones of the plurality of gate structures comprise a gate region and a gate dielectric layer disposed around the gate region. Respective ones of the plurality of dielectric layers are disposed between a first two-dimensional semiconductor material layer of a plurality of two-dimensional semiconductor material layers and a second two-dimensional semiconductor material layer of the plurality of two-dimensional semiconductor material layers. The gate dielectric layer of the respective ones of the plurality of gate structures contacts at least one of the plurality of two-dimensional semiconductor material layers.

In another embodiment, a semiconductor device comprises a nanosheet structure comprising a plurality of gate structures alternately stacked with a plurality of dielectric layers, and a plurality of two-dimensional semiconductor material layers. Respective ones of the plurality of two-dimensional semiconductor material layers are disposed between adjacent ones of the plurality of gate structures and the plurality of dielectric layers. At least one source/drain region is disposed on a side of the nanosheet structure, wherein the at least one source/drain region comprises a different material from the two-dimensional semiconductor material layers. Respective ones of the plurality of gate structures contact at least one of the plurality of two-dimensional semiconductor material layers.

In another embodiment, a semiconductor device comprises a plurality of gate structures alternately stacked with a plurality of dielectric layers, and a plurality of spacers disposed on sides of the plurality of gate structures at least one of over and under respective ones of the plurality of dielectric layers. At least one source/drain region is disposed on a side of the nanosheet structure. Sides of the respective ones of the plurality of dielectric layers contact a side of the at least one source/drain region. Sides of respective ones of the plurality of spacers contact the side of the at least one source/drain region and are coplanar with the sides of the respective ones of the plurality of dielectric layers.

These and other features and advantages of embodiments described herein will become more apparent from the accompanying drawings and the following detailed description.

### BRIEF DESCRIPTION OF THE DRAWINGS

FIG. 1 depicts a cross-sectional view of a semiconductor structure illustrating semiconductor nanosheet layers and a dummy gate layer, according to an embodiment of the invention.

FIG. 2 depicts a cross-sectional view of a semiconductor structure following dummy gate patterning and gate spacer formation, according to an embodiment of the invention.

FIG. 3 depicts a cross-sectional view of a semiconductor structure following bottom isolation layer formation, according to an embodiment of the invention.

FIG. 4 depicts a cross-sectional view of a semiconductor structure following patterning of semiconductor nanosheet layers, according to an embodiment of the invention.

FIG. 5 depicts a cross-sectional view of a semiconductor structure following lateral recessing of second sacrificial semiconductor layers and inner spacer formation, according to an embodiment of the invention.

FIG. 6A depicts a cross-sectional view of a semiconductor structure following removal of first sacrificial semiconductor layers, according to an embodiment of the invention.

FIG. 6B depicts a cross-sectional view of a semiconductor structure following deposition of two-dimensional (2D) semiconductor material, according to an embodiment of the invention.

FIG. 7A depicts a cross-sectional view of a semiconductor structure following deposition of dielectric nanosheet layers on the structure of FIG. 6A, according to an embodiment of the invention.

FIG. 7B depicts a cross-sectional view of a semiconductor structure following optional removal of portions of the 2D semiconductor material from and deposition of dielectric nanosheet layers on the structure of FIG. 6B, according to an embodiment of the invention.

FIG. 8A depicts a cross-sectional view of a semiconductor structure following deposition of a doped source/drain region on the structure of FIG. 7A, according to an embodiment of the invention.

FIG. 8B depicts a cross-sectional view of a semiconductor structure following deposition of a doped source/drain region on the structure of FIG. 7B, according to an embodiment of the invention.

FIG. 8C depicts a cross-sectional view of a semiconductor structure following growth of an epitaxial source/drain region in a structure where portions of a bottom isolation layer were removed, according to an embodiment of the invention.

FIG. 9A depicts a cross-sectional view of a semiconductor structure following dummy gate and second sacrificial semiconductor layer removal from, and replacement metal gate (RMG) formation on the structure of FIG. 8A, according to an embodiment of the invention.

FIG. 9B depicts a cross-sectional view of a semiconductor structure following dummy gate and second sacrificial semiconductor layer removal from, and RMG formation on the structure of FIG. 8B, according to an embodiment of the invention.

FIG. 9C depicts a cross-sectional view of a semiconductor structure following dummy gate and second sacrificial semiconductor layer removal from, and RMG formation on the structure of FIG. 8C, according to an embodiment of the invention.

FIG. 10A depicts a cross-sectional view of a semiconductor structure following inter-layer dielectric (ILD) layer and source/drain contact formation on the structure of FIG. 9A, according to an embodiment of the invention.

FIG. 10B depicts a cross-sectional view of a semiconductor structure following ILD layer and source/drain contact formation on the structure of FIG. 9B, according to an embodiment of the invention.

FIG. 10C depicts a cross-sectional view of a semiconductor structure following ILD layer and source/drain contact formation on the structure of FIG. 9C, according to an embodiment of the invention.

FIG. 11 depicts a cross-sectional view of the semiconductor structure in FIG. 10A in a gate to source/drain region qualification process, according to an embodiment of the present invention.

### DETAILED DESCRIPTION

Illustrative embodiments of the invention may be described herein in the context of illustrative methods for forming dielectric and two-dimensional (2D) semiconductor material layers for nanosheet devices, along with illustrative apparatus, systems and devices formed using such methods. However, it is to be understood that embodiments of the invention are not limited to the illustrative methods, apparatus, systems and devices but instead are more broadly applicable to other suitable methods, apparatus, systems and devices.

It is to be understood that the various features shown in the accompanying drawings are schematic illustrations that are not necessarily drawn to scale. Moreover, the same or similar reference numbers are used throughout the drawings to denote the same or similar features, elements, or structures, and thus, a detailed explanation of the same or similar features, elements, or structures will not be repeated for each of the drawings. Further, the terms “exemplary” and “illustrative” as used herein mean “serving as an example, instance, or illustration.” Any embodiment or design described herein as “exemplary” or “illustrative” is not to be construed as preferred or advantageous over other embodiments or designs.

A field-effect transistor (FET) is a transistor having a source, a gate, and a drain, and having action that depends on the flow of carriers (electrons or holes) along a channel that runs between the source and drain. Current through the channel between the source and drain may be controlled by a transverse electric field under the gate.

FETs are widely used for switching, amplification, filtering, and other tasks. FETs include metal-oxide-semiconductor (MOS) FETs (MOSFETs). Complementary MOS (CMOS) devices are widely used, where both n-type and p-type transistors (nFET and pFET) are used to fabricate logic and other circuitry. Source and drain regions of a FET are typically formed by adding dopants to target regions of a semiconductor body on either side of a channel, with the gate being formed above the channel. The gate includes a gate dielectric over the channel and a gate conductor over the gate dielectric. The gate dielectric is an insulator material that prevents large leakage current from flowing into the channel when voltage is applied to the gate conductor while allowing applied gate voltage to produce a transverse electric field in the channel.

Various techniques may be used to reduce the size of FETs. One technique is through the use of fin-shaped channels in FinFET devices. Before the advent of FinFET arrangements, CMOS devices were typically substantially planar along the surface of the semiconductor substrate, with the exception of the FET gate disposed over the top of the channel. FinFETs utilize a vertical channel structure, increasing the surface area of the channel exposed to the gate. Thus, in FinFET structures the gate can more effectively control the channel, as the gate extends over more than one side or surface of the channel. In some FinFET arrangements, the gate encloses three surfaces of the three-dimensional channel, rather than being disposed over just the top surface of a traditional planar channel.

Another technique useful for reducing the size of FETs is through the use of stacked nanosheet channels formed over a semiconductor substrate. Stacked nanosheets may be two-dimensional nanostructures, such as sheets having a thickness range on the order of 1 to 100 nanometers (nm). Nanosheets and nanowires are viable options for scaling to 7 nm and beyond. A general process flow for formation of a nanosheet stack involves selectively removing sacrificial layers, which may be formed of silicon germanium (SiGe), between sheets of channel material, which may be formed of silicon (Si).

For continued scaling (e.g., to 2.5 nm and beyond), next-generation stacked FET devices may be used. Next-generation stacked FET devices provide a complex gate-all-around (GAA) structure. Conventional GAA FETs, such as nanosheet FETs, may stack multiple p-type nanowires or nanosheets on top of each other in one device, and may stack multiple n-type nanowires or nanosheets on top of each other in another device. Next-generation stacked FET structures provide improved track height scaling, leading to structural gains (e.g., such as 30-40% structural gains for different types of devices, such as logic devices, static random-access memory (SRAM) devices, etc.). In next-generation stacked FET structures, n-type and p-type nanowires or nanosheets are stacked on each other, eliminating n-to-p separation bottlenecks and reducing the device area footprint. There is, however, a continued desire for further scaling and reducing the size of FETs.

As discussed above, various techniques may be used to reduce the size of FETs, including through the use of fin-shaped channels in FinFET devices, through the use of stacked nanosheet channels formed over a semiconductor substrate, and next-generation stacked FET devices.

Although embodiments of the present invention are discussed in connection with nanosheet stacks, the embodiments of the present invention are not necessarily limited thereto, and may similarly apply to nanowire stacks.

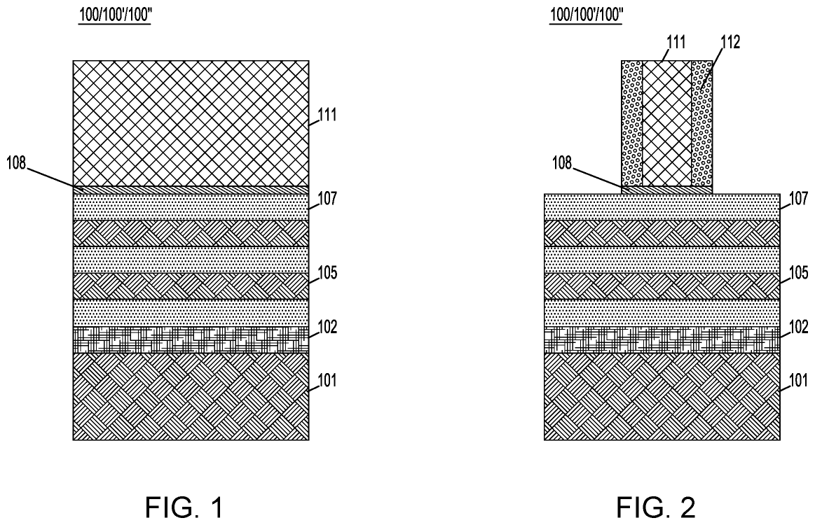

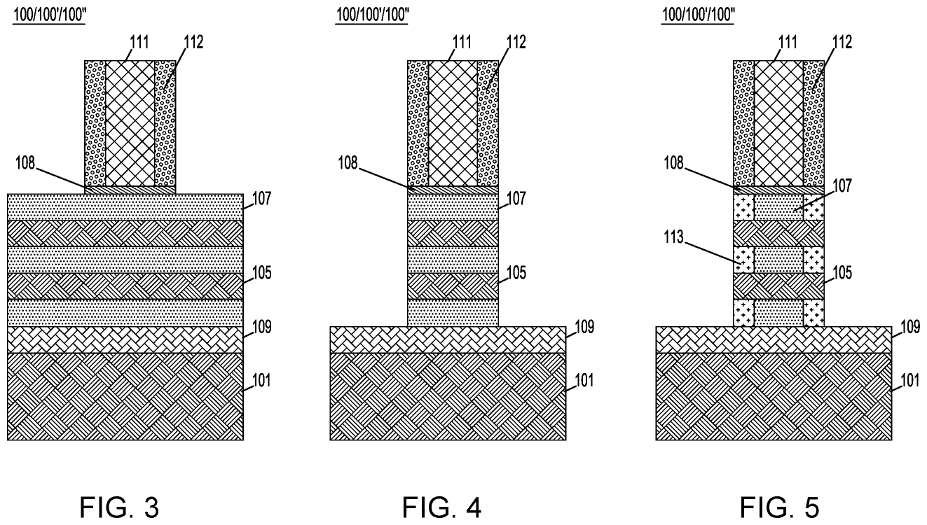

Referring to FIG. 1, a semiconductor structure 100, 100′ or 100″ includes a stacked structure of first sacrificial layers 105 and second sacrificial layers 107. In an illustrative embodiment, the first sacrificial layers 105 comprise silicon and the second sacrificial layers 107 comprise silicon germanium (SiGe). In illustrative embodiments, the second sacrificial layers 107 comprise a germanium concentration of about 25% (e.g., SiGe25), but the embodiments are not necessarily limited to SiGe25 for the second sacrificial layers 107. The lowermost second sacrificial layer 107 is formed on an additional sacrificial layer 102 including, for example, SiGe with a different concentration of germanium than that of the second sacrificial layers 107. For example, the additional sacrificial layer 102 has, but is not necessarily limited to, a germanium concentration of about 55% (e.g., SiGe55). As explained in more detail herein, the additional sacrificial layer 102 has a different concentration of germanium than the second sacrificial layers 107 so that the additional sacrificial layer 102 can be selectively etched and removed with respect to second sacrificial layers 107 when forming a bottom isolation layer (see, e.g., FIG. 3 including bottom isolation layer 109).

A semiconductor substrate 101 comprises semiconductor material including, but not limited to, silicon (Si), III-V, II-V compound semiconductor materials or other like semiconductor materials. In addition, multiple layers of the semiconductor materials can be used as the semiconductor material of the semiconductor substrate 101. The semiconductor substrate 101 may also be referred herein to as a semiconductor layer.

The first sacrificial layers 105 and second sacrificial layers 107 are epitaxially grown in an alternating and stacked configuration on the additional sacrificial layer 102. A lowermost second sacrificial layer 107 is followed by a lowermost first sacrificial layer 105 on the lowermost second sacrificial layer 107, which is followed by a next second sacrificial layer 107 on the lowermost first sacrificial layer 105, and so on. As can be understood, the first and second sacrificial layers 105 and 107 are epitaxially grown from their corresponding underlying semiconductor layers.

While two first sacrificial layers 105 and three second sacrificial layers 107 are shown, the embodiments of the present invention are not necessarily limited to the shown number of first and second sacrificial layers 105 and 107, and there may be more or less layers in the same alternating configuration depending on design constraints. As described further herein, the first sacrificial layers 105 are eventually removed and replaced by dielectric layers or dielectric layers and two-dimensional semiconductor material layers depending on the embodiments, and the second sacrificial layers 107 are eventually removed and replaced by gate structures.

The terms “epitaxial growth and/or deposition” and “epitaxially formed and/or grown,” mean the growth of a semiconductor material (crystalline material) on a deposition surface of another semiconductor material (crystalline material), in which the semiconductor material being grown (crystalline over layer) has substantially the same crystalline characteristics as the semiconductor material of the deposition surface (seed material). In an epitaxial deposition process, the chemical reactants provided by the source gases are controlled, and the system parameters are set so that the depositing atoms arrive at the deposition surface of the semiconductor substrate with sufficient energy to move about on the surface such that the depositing atoms orient themselves to the crystal arrangement of the atoms of the deposition surface. Therefore, an epitaxially grown semiconductor material has substantially the same crystalline characteristics as the deposition surface on which the epitaxially grown material is formed.

The epitaxial deposition process may employ the deposition chamber of a chemical vapor deposition type apparatus, such as a metal-organic chemical vapor deposition (MOCVD), rapid thermal chemical vapor deposition (RTCVD), ultra-high vacuum chemical vapor deposition (UHVCVD), or a low-pressure chemical vapor deposition (LPCVD) apparatus. A number of different sources may be used for the epitaxial deposition of the in situ doped semiconductor material. In some embodiments, the gas source for the deposition of an epitaxially formed semiconductor material may include silicon (Si) deposited from silane, disilane, trisilane, tetrasilane, hexachlorodisilane, tetrachlorosilane, dichlorosilane, trichlorosilane, and combinations thereof. In other examples, when the semiconductor material includes germanium, a germanium gas source may be selected from the group consisting of germane, digermane, halogermane, dichlorogermane, trichlorogermane, tetrachlorogermane and combinations thereof. The temperature for epitaxial deposition typically ranges from 450° C. to 900° C. Although higher temperature typically results in faster deposition, the faster deposition may result in crystal defects and film cracking.

In a non-limiting illustrative embodiment, a height (e.g., vertical thickness in the cross-sectional views) of the first sacrificial layers 105 can be in the range of about 3 nm to about 15 nm depending on the application of the device. Also, in a non-limiting illustrative embodiment, a height (e.g., vertical thickness in the cross-sectional views) of the second sacrificial layers 107 can be in the range of about 3 nm to about 15 nm depending on the desired process and application. In accordance with an embodiment of the present invention, each of the second sacrificial layers 107 has the same or substantially the same composition and size as each other, and each of the first sacrificial layers 105 has the same or substantially the same composition and size as each other.

Although not shown, portions of the nanosheet stacks comprising the first sacrificial layers 105 and second sacrificial layers 107 are removed, portions of the additional sacrificial layer 102 are removed and portions of the semiconductor substrate 101 are recessed. Isolation regions (e.g., shallow trench isolation (STI) regions) are formed between the remaining nanosheet stacks, and remaining portions of the additional sacrificial layer 102 and the semiconductor substrate 101. The dielectric material of the isolation regions may comprise, for example, silicon nitride (SiN), silicon oxynitride (SiON), silicon-carbon-nitride (SiCN), boron nitride (BN), silicon boron nitride (SiBN), silicoboron carbonitride (SiBCN), silicon oxycarbonitride (SiOCN) and combinations thereof, and is deposited using deposition techniques such as, for example, chemical vapor deposition (CVD), plasma enhanced CVD (PECVD), radio-frequency CVD (RFCVD), physical vapor deposition (PVD), atomic layer deposition (ALD), molecular beam deposition (MBD), pulsed laser deposition (PLD), and/or liquid source misted chemical deposition (LSMCD).

A dielectric layer 108 and a dummy gate portion 111 are formed on the uppermost second sacrificial layer 107. Although not shown, the dummy gate portion 111 is formed around the stacked nanosheet configuration of the first sacrificial layers 105 and second sacrificial layers 107. The dielectric layer 108 includes, but is not necessarily limited to, silicon oxide (SiOₓ) (where x is for example, 2, 1.99 or 2.01), silicon oxycarbide (SiOC), SiN, SiON, SiCN, BN, SiBCN, SiOCN or some other dielectric. The dummy gate portion 111 includes, but is not necessarily limited to, an amorphous silicon (a-Si) layer. The dielectric layer 108 and the dummy gate portion 111 are deposited using deposition techniques such as, for example, CVD, PECVD, RFCVD, PVD, ALD, MBD, PLD, LSMCD, sputtering and/or plating, followed by a planarization process, such as, chemical mechanical planarization (CMP), and lithography and etching steps to remove excess dummy gate material, and pattern the deposited layer.

Although not shown, a hardmask layer is formed on the dummy gate portion 111, and exposed portions of the dummy gate portion 111 and dielectric layer 108 not under the hardmask layer are removed to leave remaining parts of the dummy gate portion 111 and dielectric layer 108 as shown in FIG. 2. Gate spacers 112 are formed on sides of the dummy gate portion 111 by one or more of the deposition techniques noted in connection with deposition of the dummy gate material. The spacer material can comprise for example, one or more dielectrics, including, but not necessarily limited to, SiN, SiON, SiOC, SiCN, BN, SiBN, SiBCN, SiOCN, SiOₓ, and combinations thereof. The gate spacers 112 can be formed by any suitable techniques such as deposition followed by directional etching. Deposition may include but is not limited to, ALD or CVD. Directional etching may include but is not limited to, reactive ion etching (RIE).

Referring to FIG. 3, the additional sacrificial layer 102 between the lowermost second sacrificial layer 107 and semiconductor substrate 101 is removed using, for example, an aqueous solution containing hydrogen peroxide (H₂O₂) or a gas containing hydrogen fluoride (HF) to selectively etch the additional sacrificial layer 102 with respect to the semiconductor substrate 101, the first sacrificial layers 105 and the second sacrificial layers 107. The selective etching removes the additional sacrificial layer 102 to form a vacant area where the bottom isolation layer 109 is formed.

Dielectric material is deposited in place of the additional sacrificial layer 102 using deposition techniques such as, for example, CVD, PECVD, RFCVD, PVD, ALD, MBD, PLD, and/or LSMCD, followed by an etch back to form the bottom isolation layer 109 on the semiconductor substrate 101 in place of the additional sacrificial layer 102. The bottom isolation layer 109 may comprise, for example, silicon oxide (SiOₓ) (where x is for example, 2, 1.99 or 2.01), silicon oxycarbide (SiOC), SiN, SiON, SiCN, BN, SiBCN, SiOCN or some other dielectric. The bottom isolation layer 109 is under a bottom surface of the lowermost second sacrificial layer 107.

Referring to FIG. 4, exposed portions of the stacked first sacrificial layers 105 and second sacrificial layers 107, which are not under the gate spacers 112, dummy gate portion 111 and dielectric layer 108, are removed using, for example, an etching process, such as RIE, where the gate spacers 112, dummy gate portion 111 and dielectric layer 108 are used as a mask. The portions of the stacked structures of first sacrificial layers 105 and second sacrificial layers 107 under the gate spacers 112, under the dummy gate portion 111 and under the dielectric layer 108 remain after the etching process, and portions of the first sacrificial layers 105 and second sacrificial layers 107 in areas that correspond to where source/drain regions will be formed are removed. The process for removal of the exposed portions of the stacked first sacrificial layers 105 and second sacrificial layers 107 includes, for example, CF₄ gas to selectively remove SiGe and a RIE process with H₂/CF₄ plasma to remove silicon.

Referring to FIG. 5, due to, for example, germanium in the second sacrificial layers 107, lateral etching of the second sacrificial layers 107 can be performed selective to the first sacrificial layers 105, such that the side portions of the second sacrificial layers 107 can be removed to create vacant areas to be filled in by inner spacers 113. The material of the inner spacers 113 can comprise, but is not necessarily limited to, a nitride, such as, SiN, SiON, SiCN, BN, SiBN, SiBCN or SiOCN. Gate spacers 112 are positioned on the nanosheet stacks on opposite lateral sides of the dummy gate portion 111. In an illustrative embodiment, the gate spacers 112 are formed from the same or similar material to that of the inner spacers 113. Like the gate spacers 112, the inner spacers 113 can be formed by any suitable techniques such as deposition followed by directional etching.

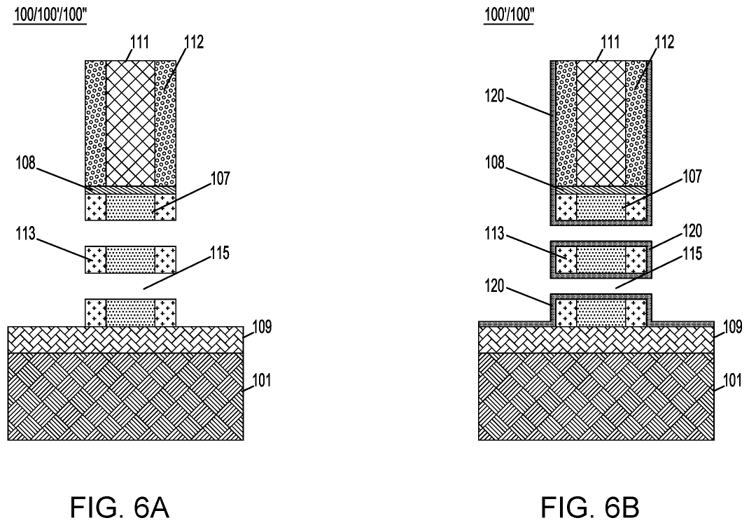

Referring to FIG. 6A, the first sacrificial layers 105 are selectively removed with respect to the second sacrificial layers 107 to create vacant areas 115. The selective removal can be performed using, for example, ammonium hydroxide. Referring to FIG. 6B, for semiconductor structures 100′ and 100″, two-dimensional (2D) semiconductor material layers 120 are deposited on exposed portions of the second sacrificial layers 107, dielectric layer 108, bottom isolation layer 109, gate spacers 112 and inner spacers 113. Deposition techniques to deposit the 2D semiconductor material layers 120 may include, but are not limited to, ALD or CVD. The 2D semiconductor material layers 120 comprise, for example, a transition metal dichalcogenide that includes a transition metal (e.g., molybdenum (Mo) or tungsten (W)) and a chalcogen atom (sulfur (S), selenium (Se), or tellurium (Te)). Exemplary transition metal dichalcogenides include, but are not limited to, molybdenum disulfide (MoS₂), hafnium disulfide (HfS₂), zirconium disulfide (ZrS₂), tungsten disulfide (WS₂), tin sulfide (SnS), and tungsten diselenide (WSe₂). Alternatively, the 2D semiconductor material layers 120 may comprise graphene (C).

As shown in FIG. 6B, the deposited thickness of the 2D semiconductor material layers 120 is controlled such that the vacant areas 115 are only partially filled by the 2D semiconductor material layers 120. As explained in more detail herein, the 2D semiconductor material layers 120 in the vacant areas 115 form channel layers in the semiconductor structures 100′ and 100″. In illustrative embodiments, the 2D semiconductor material layers 120 have thicknesses on the atomic scale. For example, the 2D semiconductor material layers 120 may include a single monolayer of atoms arranged in a thin sheet. Graphene, for example, includes a monolayer of carbon atoms.

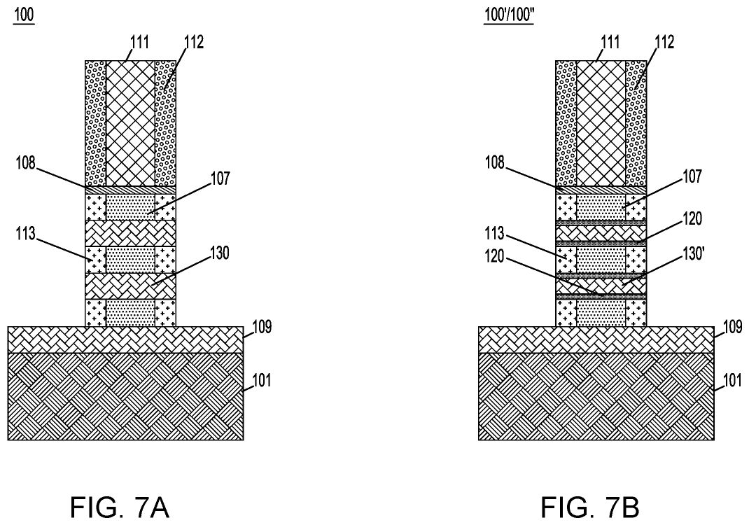

In an alternative embodiment, referring to FIG. 7A, in the semiconductor structure 100, following the selective removal the first sacrificial layers 105 with respect to the second sacrificial layers 107 to create vacant areas 115, instead of depositing the 2D semiconductor material layers 120 as in FIG. 6B, dielectric layers 130 are deposited to fill in the vacant areas 115. Dielectric material forming the dielectric layers 130 is deposited using deposition techniques such as, for example, CVD, PECVD, RFCVD, PVD, ALD, MBD, PLD, and/or LSMCD, followed by an etch back to form the dielectric layers 130 in the vacant areas 115. The dielectric layers 130 may comprise, for example, a material or materials similar to that of the bottom isolation layer 109.

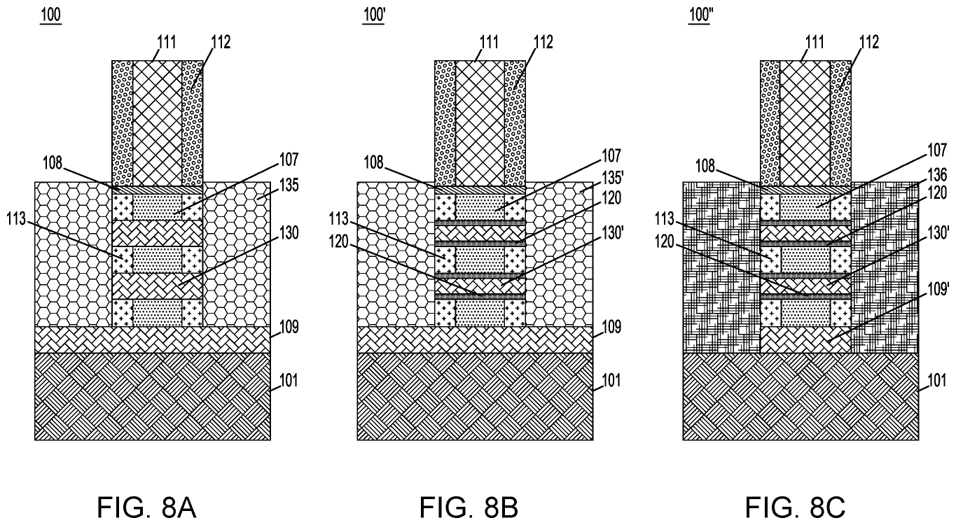

Referring to FIG. 7B, for the semiconductor structures 100′ and 100″, following deposition of the 2D semiconductor material layers 120, portions of the 2D semiconductor material layers 120 not in the vacant areas 115 are removed using, for example, acetone and UV-ozone, etc. Then, similar to what is described in connection with FIG. 7A, dielectric layers 130′ are deposited on the remaining portions of the 2D semiconductor material layers 120 to fill in the remaining portions of the vacant areas 115 not occupied by the remaining portions of the 2D semiconductor material layers 120. Dielectric material forming the dielectric layers 130′ is deposited using deposition techniques such as, for example, CVD, PECVD, RFCVD, PVD, ALD, MBD, PLD, and/or LSMCD, followed by an etch back to form the dielectric layers 130′ in the remaining portions of the vacant areas 115. The dielectric layers 130′ may comprise, for example, a material or materials similar to that of the dielectric layers 130, and can have a greater thickness (e.g., vertical thickness in the cross-sectional views) than that of the 2D semiconductor material layers 120. In alternative embodiments, the portions of the 2D semiconductor material layers 120 not in the vacant areas 115 are not removed prior to deposition of the dielectric layers 130′. In an alternative embodiment in connection with semiconductor structure 100′, the portions of the 2D semiconductor material layers 120 remain on the bottom isolation layer 109 and on sides of the dielectric layer 108, gate spacers 112 and inner spacers 113 in the semiconductor structure 100′. In an alternative embodiment in connection with semiconductor structure 100″, the portions of the 2D semiconductor material layers 120 remain on sides of the dielectric layer 108, gate spacers 112 and inner spacers 113 in the semiconductor structure 100″. As explained in more detail in connection with FIG. 8C, portions of the bottom isolation layer 109 on which the 2D semiconductor material layers 120 would remain are removed so that an epitaxial source/drain region can be grown.

Referring to FIGS. 8A and 8B, in the semiconductor structures 100 and 100′, source/drain regions 135 and 135′ are deposited on the bottom isolation layer 109 on the sides of the stacked structures. In more detail, in FIG. 8A, a source/drain region 135 is deposited on the structure from FIG. 7A on bottom isolation layer 109 and on the sides of the stacked structure comprising the second sacrificial layers 107 alternately stacked with the dielectric layers 130. In FIG. 8B, a source/drain region 135′ is deposited on the structure from FIG. 7A on the bottom isolation layer 109 and on the sides of the stacked structure comprising the second sacrificial layers 107 alternately stacked with the dielectric layers 130′, wherein the dielectric layers 130′ are disposed between 2D semiconductor material layers 120 on top of and under bottom surfaces of respective ones of the dielectric layers 130′. Since there is no exposed semiconductor layer from which epitaxial growth can occur, the source/drain regions 135 and 135′ are deposited using, for example, CVD, PECVD, RFCVD, PVD, ALD, MBD, PLD, and/or LSMCD. The source/drain regions 135 and 135′may comprise a different material from that of the 2D semiconductor material layers 120 such as, for example, amorphous silicon (a-Si) or a combination of semiconductor metals.

In the case of n-type FETS (nFETs), the source/drain regions 135 and 135′ can comprise a-Si doped with n-type dopants including, for example, phosphorus (P), arsenic (As) and antimony (Sb). In the case of p-type FETS (pFETs), the source/drain regions 135 and 135′ can comprise a-Si doped with p-type dopants including, for example, boron (B), boron fluoride (BF₂), gallium (Ga), indium (In), and thallium (Tl). Side surfaces of the inner spacers 113 and dielectric layers 130, which are coplanar with each other, contact side surfaces of source/drain region 135. The top surface of the source/drain region 135 is above the top surface of the uppermost second sacrificial layer 107 and dielectric layer 108. Side surfaces of the inner spacers 113, 2D semiconductor material layers 120 and dielectric layers 130′, which are coplanar with each other, contact side surfaces of source/drain region 135′. The top surface of the source/drain region 135′ is above the top surface of the uppermost second sacrificial layer 107 and dielectric layer 108.

In another embodiment, referring to FIG. 8C, following the processing described in connection with FIG. 7B, in a semiconductor structure 100″, exposed portions of the bottom isolation layer 109 are removed to expose portions of the semiconductor substrate 101. The process for removal of the exposed portions of the bottom isolation layer 109 to result in the remaining bottom isolation layer 109′ includes, for example, etching with CF₄/H₂, CF₄/O₂/N₂, SF₆/O₂/N₂, SF₆/CH₄/N₂ and/or SF₆/CH₄/N₂/O₂. Following removal of the exposed portions of the bottom isolation layer 109, epitaxial source/drain region 136 is grown from the exposed portions of the semiconductor substrate 101. Side surfaces of the inner spacers 113, 2D semiconductor material layers 120 and dielectric layers 130′, which are coplanar with each other, contact side surfaces of epitaxial source/drain region 136. The top surface of the epitaxial source/drain region 136 is above the top surface of the uppermost second sacrificial layer 107 and dielectric layer 108.

According to a non-limiting embodiment of the present invention, the conditions of the epitaxial growth process for the epitaxial source/drain region 136 are, for example, RTCVD epitaxial growth using SiH₄, SiH₂Cl₂, GeH₄, CH₃SiH₃, B₂H₆, PF₃, and/or H₂ gases with temperature and pressure ranges of about 450° C. to about 800° C., and about 5 Torr—about 300 Torr. In the case of n-type FETS (nFETs), the epitaxial source/drain region 136 can comprise silicon doped with n-type dopants including, for example, phosphorus (P), arsenic (As) and antimony (Sb). In the case of p-type FETS (pFETs), the epitaxial source/drain region 136 can comprise silicon doped with p-type dopants including, for example, boron (B), boron fluoride (BF₂), gallium (Ga), indium (In), and thallium (Tl). The epitaxial source/drain region 136 comprises a different material from that of the 2D semiconductor material layers 120.

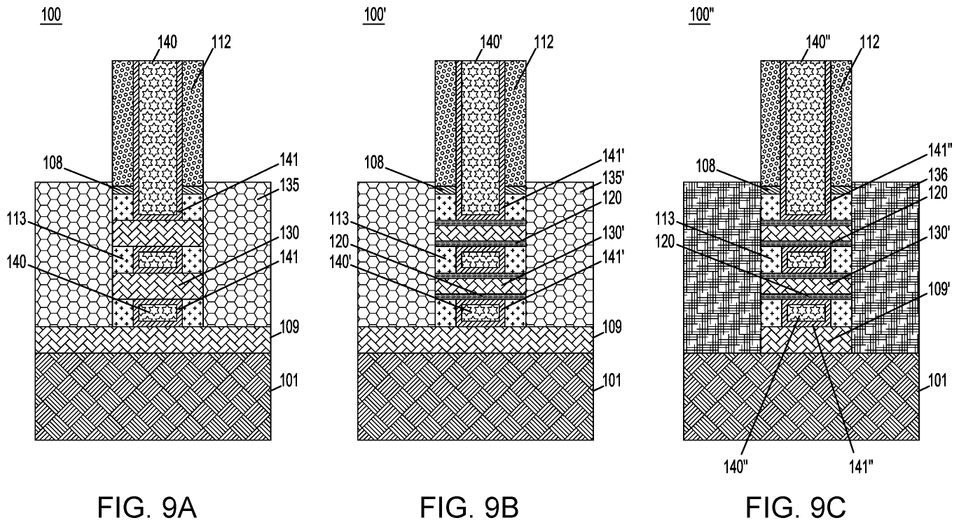

Referring to FIGS. 9A, 9B and 9C, the dummy gate portions 111 are selectively removed to create vacant areas where gate structures will be formed in place of the dummy gate portions 111. The selective removal can be performed using, for example, hot ammonia to remove a-Si. In addition, the second sacrificial layers 107 are selectively removed to create vacant areas where gate structures will be formed in place of the second sacrificial layers 107. In the semiconductor structure 100, the second sacrificial layers 107 are selectively removed with respect to the inner spacers 113 and the dielectric layers 130. In the semiconductor structures 100′ and 100″, the second sacrificial layers 107 are selectively removed with respect to the inner spacers 113, 2D semiconductor material layers 120 and the dielectric layers 130′. The selective removal can be performed using, for example, a dry HCl etch.

Following removal of the dummy gate portions 111 and second sacrificial layers 107, gate structures comprising gate regions 140, 140′ and 140″, and gate dielectric layers 141, 141′ and 141″ are formed in the vacant portions left by removal of the dummy gate portions 111 and the second sacrificial layers 107. In illustrative embodiments, each gate dielectric layer 141, 141′ and 141″ respectively corresponding to semiconductor structures 100, 100′ and 100″ comprises, for example, a high-K dielectric layer including, but not necessarily limited to, HfO₂ (hafnium oxide), ZrO₂ (zirconium dioxide), hafnium zirconium oxide, Al₂O₃ (aluminum oxide), and Ta₂O₅ (tantalum oxide). Examples of high-k materials also include, but are not limited to, metal oxides such as hafnium silicon oxynitride, lanthanum oxide, lanthanum aluminum oxide, zirconium oxide, zirconium silicon oxide, zirconium silicon oxynitride, tantalum oxide, titanium oxide, barium strontium titanium oxide, barium titanium oxide, strontium titanium oxide, yttrium oxide, aluminum oxide, lead scandium tantalum oxide, and lead zinc niobate. According to an embodiment, each gate region 140, 140′ and 140″ respectively corresponding to semiconductor structures 100, 100′ and 100″, comprises a work-function metal (WFM) layer, including but not necessarily limited to, for a pFET, titanium nitride (TiN), tantalum nitride (TaN) or ruthenium (Ru), and for an nFET, TiN, titanium aluminum nitride (TiAlN), titanium aluminum carbon nitride (TiAlCN), titanium aluminum carbide (TiAlC), tantalum aluminum carbide (TaAlC), tantalum aluminum carbon nitride (TaAlCN) or lanthanum (La) doped TiN, TaN, which can be deposited on the gate dielectric layer. Each gate region 140, 140′ and 140″ can also further include a gate metal layer including, but not necessarily limited to, metals, such as, for example, tungsten, cobalt, zirconium, tantalum, titanium, aluminum, ruthenium, copper, metal carbides, metal nitrides, transition metal aluminides, tantalum carbide, titanium carbide, tantalum magnesium carbide, or combinations thereof deposited on the WFM layer and the gate dielectric layer. It should be appreciated that various other materials may be used for each gate region 140, 140′ and 140″ as desired. The inner spacers 113 are disposed on sides of the gate structures over and/or under the respective ones of the dielectric layers 130 or 130′.

In the semiconductor structure 100, the gate dielectric layers 141 of the respective ones of the plurality of gate structures contact at least one of the dielectric layers 130. The gate dielectric layers 141 of the respective ones of the plurality of gate structures, which are disposed around the gate regions 140 contact a top surface and/or a bottom surface of one or more adjacent dielectric layers 130. In the semiconductor structures 100′ and 100″, the gate dielectric layers 141′ and 141″ of the respective ones of the plurality of gate structures contact at least one of the 2D semiconductor material layers 120. The gate dielectric layers 141′ and 141″ of the respective ones of the plurality of gate structures, which are disposed around the gate regions 140′ and 140″ contact a top surface and/or a bottom surface of one or more adjacent 2D semiconductor material layers 120.

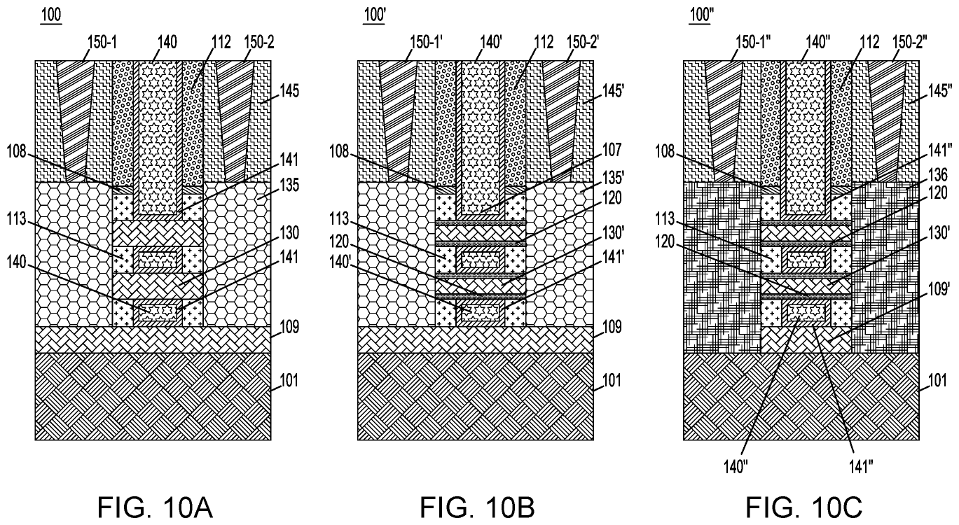

Referring to FIGS. 10A-10C, inter-layer dielectric (ILD) layers 145, 145′ and 145″ are deposited on the semiconductor structures 100′, 100′ and 100″ from FIGS. 9A, 9B and 9C, respectively, to fill in portions on and around the source/drain regions 135, 135′ and epitaxial source/drain region 136, and on and around the gate structures. The ILD layers 145, 145′ and 145″ are deposited using deposition techniques such as, for example, CVD, PECVD, RFCVD, PVD, ALD, MBD, PLD, and/or LSMCD, followed by a planarization process, such as, chemical mechanical planarization (CMP) to remove excess portions of the ILD layers 145, 145′ and 145″ deposited on top of the gate spacers 112 and gate structures. The ILD layers 145, 145′ and 145″ may comprise, for example, SiOₓ, SiOC, SiOCN or some other dielectric.

Source/drain contacts 150-1 and 150-2, 150-1′ and 150-2′, 150-1″ and 150-2″ (collectively “source/drain contacts 150) are respectively formed in the ILD layers 145, 145′ and 145”. The source/drain contacts 150-1 and 150-2 contact the source/drain region 135, the source/drain contacts 150-1′ and 150-2′ contact the source/drain region 135′ and the source/drain contacts 150-1″ and 150-2″ contact the epitaxial source/drain region 136. In forming the source/drain contacts 150, openings are formed through portions of the ILD layers 145, 145′ and 145″. The openings expose portions the source/drain regions 135, 135′ or epitaxial source drain region 136 on which the source/drain contacts 150 are to be formed. According to an embodiment, masks are formed on parts of the ILD layers 145, 145′ and 145″, and exposed portions of the ILD layers 145, 145′ and 145″ corresponding to where the openings are to be formed are removed using, for example, a dry etching process using a RIE or ion beam etch (IBE) process, a wet chemical etch process or a combination of these etching processes. A dry etch may be performed using a plasma. Such wet or dry etch processes include, for example, IBE by Ar/CHF3 based chemistry.

Metal layers are deposited in the openings to form the source/drain contacts 150. The metal layers comprise, for example, a silicide layer, such as Ni, Ti, NiPt, etc., a metal adhesion layer, such as TiN, and a conductive metal fill layer, such as W, Al, Co, Ru, etc., and can be deposited using, for example, a deposition technique such as CVD, PECVD, RFCVD, PVD, ALD, MBD, PLD, LSMCD, sputtering and/or plating, followed by a planarization process such as, CMP to remove excess portions of the metal layers from on top of the ILD layers 145, 145′ and 145″. The source/drain contacts 150 extend through the ILD layers 145, 145′ and 145″ to land on and contact the corresponding source/drain regions 135, 135′ or epitaxial source/drain region 136.

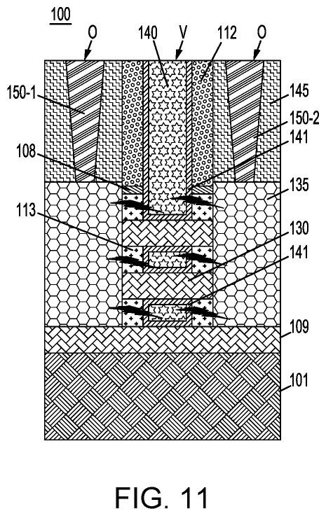

FIG. 11 depicts a cross-sectional view of the semiconductor structure 100 from FIG. 10A in a gate to source/drain region qualification process. The gate to source/drain region qualification process evaluates whether the inner spacers 113 adequately isolate the source/drain region 135 from the gate structures (e.g., gate regions 140). In the gate to source/drain region qualification process, a voltage (V) is applied to the gate regions 140 and no voltage (0) is applied to the source/drain contacts 150-1 and 150-2 (and consequently the source/drain region 135). If a voltage is identified at the source/drain region 135, then this may indicate that one or more of the inner spacers 113 do not adequately isolate the gate structures from the source/drain region 135. The lightning-like shapes in FIG. 11 indicate potential failure points, where the inner spacers 113 may be too narrow (e.g., horizontal width in the cross-sectional views) to effectively electrically isolate the source/drain region 135 from the gate structures. Inner spacer evaluation may be crucial for Vmax support processes when using low-k spacer materials and scaling down sizes for thickness reduction.

Semiconductor devices and methods for forming the same in accordance with the above-described techniques can be employed in various applications, hardware, and/or electronic systems. Suitable hardware and systems for implementing embodiments of the invention may include, but are not limited to, personal computers, communication networks, electronic commerce systems, portable communications devices (e.g., cell and smart phones), solid-state media storage devices, functional circuitry, etc. Systems and hardware incorporating the semiconductor devices are contemplated embodiments of the invention. Given the teachings provided herein, one of ordinary skill in the art will be able to contemplate other implementations and applications of embodiments of the invention.

In some embodiments, the above-described techniques are used in connection with semiconductor devices that may require or otherwise utilize, for example, CMOSs, MOSFETs, and/or FinFETs. By way of non-limiting example, the semiconductor devices can include, but are not limited to CMOS, MOSFET, and FinFET devices, and/or semiconductor devices that use CMOS, MOSFET, and/or FinFET technology.

Various structures described above may be implemented in integrated circuits. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either: (a) an intermediate product, such as a motherboard, or (b) an end product. The end product can be any product that includes integrated circuit chips, ranging from toys and other low-end applications to advanced computer products having a display, a keyboard or other input device, and a central processor.

As noted above, the embodiments provide techniques and structures for forming dielectric and two-dimensional (2D) semiconductor material layers for nanosheet devices. With conventional approaches, when gate to source/drain region qualification processes are performed, it is difficult to determine whether the inner spacers effectively isolate the source/drain regions from the gate structures because the leakage may occur through channel layers. The embodiments include dielectric layers in place of channel layers so that inner spacers may be identified when isolation is not adequate. Two-dimensional semiconductor material layers can be added on top of and below dielectric layers and used as channel layers in an operational device.

For example, respective ones of a plurality of dielectric layers (e.g., dielectric layers 130′) are disposed between a first 2D semiconductor material layer of a plurality of 2D semiconductor material layers (e.g., 2D semiconductor material layers 120) and a second 2D semiconductor material layer of the plurality of 2D semiconductor material layers. In illustrative embodiments, the plurality of 2D semiconductor material layers 120 are thinner (e.g., smaller vertical thickness in the cross-sectional views) than the respective ones of the plurality of dielectric layers 130′. A plurality of gate structures (including gate regions 140′ and 140″, and gate dielectric layers 141′ and 141″) are alternately stacked with the dielectric layers 130′, and respective ones of the 2D semiconductor material layers 120 are disposed between adjacent ones of the plurality of gate structures and the dielectric layers 130′. Respective ones of the plurality of gate structures contact at least one of the 2D semiconductor material layers 120. In illustrative embodiments, the dielectric layers (e.g., dielectric layers 130 and 130′) are wider (e.g., in the horizontal direction in the cross-sectional views) than the respective ones of the plurality of gate structures.

It should be understood that the various layers, structures, and regions shown in the figures are schematic illustrations that are not drawn to scale. In addition, for ease of explanation, one or more layers, structures, and regions of a type commonly used to form semiconductor devices or structures may not be explicitly shown in a given figure. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

Moreover, the same or similar reference numbers are used throughout the figures to denote the same or similar features, elements, or structures, and thus, a detailed explanation of the same or similar features, elements, or structures are not repeated for each of the figures. It is to be understood that the terms “approximately” or “substantially” as used herein with regard to thicknesses, widths, percentages, ranges, temperatures, times and other process parameters, etc., are meant to denote being close or approximate to, but not exactly. For example, the term “approximately” or “substantially” as used herein implies that a small margin of error is present, such as ±5%, preferably less than 2% or 1% or less than the stated amount.

In the description above, various materials, dimensions and processing parameters for different elements are provided. Unless otherwise noted, such materials are given by way of example only and embodiments are not limited solely to the specific examples given. Similarly, unless otherwise noted, all dimensions and process parameters are given by way of example and embodiments are not limited solely to the specific dimensions or ranges given.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor device comprising:
a stacked structure comprising a plurality of gate structures alternately stacked with a plurality of dielectric layers;
wherein respective ones of the plurality of gate structures comprise a gate region and a gate dielectric layer disposed around the gate region;
wherein respective ones of the plurality of dielectric layers are disposed between a first two-dimensional semiconductor material layer of a plurality of two-dimensional semiconductor material layers and a second two-dimensional semiconductor material layer of the plurality of two-dimensional semiconductor material layers; and
wherein the gate dielectric layer of the respective ones of the plurality of gate structures contacts at least one of the plurality of two-dimensional semiconductor material layers.

2. The semiconductor device of claim 1, further comprising at least one source/drain region disposed on a side of the stacked structure, wherein sides of respective ones of the plurality of two-dimensional semiconductor material layers and sides of the respective ones of the plurality of dielectric layers are disposed on a side of the at least one source/drain region.

3. The semiconductor device of claim 2, wherein the sides of the respective ones of the plurality of two-dimensional semiconductor material layers and the sides of the respective ones of the plurality of dielectric layers contact the side of the at least one source/drain region.

4. The semiconductor device of claim 3, wherein:
the stacked structure further comprises a plurality of spacers disposed on sides of the plurality of gate structures at least one of over and under the respective ones of the plurality of dielectric layers; and
sides of respective ones of the plurality of spacers contact the side of the at least one source/drain region.

5. The semiconductor device of claim 2, wherein:
the stacked structure further comprises a plurality of spacers disposed on sides of the plurality of gate structures at least one of over and under the respective ones of the plurality of dielectric layers; and
sides of respective ones of the plurality of spacers are coplanar with the sides of the respective ones of the plurality of two-dimensional semiconductor material layers disposed on the side of the at least one source/drain region.

6. The semiconductor device of claim 2, wherein:
the stacked structure further comprises a plurality of spacers disposed on sides of the plurality of gate structures at least one of over and under the respective ones of the plurality of dielectric layers; and
sides of respective ones of the plurality of spacers are coplanar with the sides of the respective ones of the plurality of dielectric layers disposed on the side of the at least one source/drain region.

7. The semiconductor device of claim 2, wherein the at least one source/drain region comprises amorphous silicon.

8. The semiconductor device of claim 2, wherein the at least one source/drain region comprises an epitaxial semiconductor material.

9. The semiconductor device of claim 1, wherein respective ones of the plurality of two-dimensional semiconductor material layers are thinner than the respective ones of the plurality of dielectric layers.

10. A semiconductor device comprising:
a nanosheet structure comprising:
a plurality of gate structures alternately stacked with a plurality of dielectric layers; and
a plurality of two-dimensional semiconductor material layers, wherein respective ones of the plurality of two-dimensional semiconductor material layers are disposed between adjacent ones of the plurality of gate structures and the plurality of dielectric layers; and
at least one source/drain region disposed on a side of the nanosheet structure, wherein the at least one source/drain region comprises a different material from the two-dimensional semiconductor material layers;
wherein respective ones of the plurality of gate structures contact at least one of the plurality of two-dimensional semiconductor material layers.

11. The semiconductor device of claim 10, wherein the respective ones of the plurality of gate structures comprise a gate region and a gate dielectric layer disposed around the gate region.

12. The semiconductor device of claim 10, wherein sides of the respective ones of the plurality of two-dimensional semiconductor material layers and sides of respective ones of the plurality of dielectric layers contact a side of the at least one source/drain region.

13. The semiconductor device of claim 12, wherein:
the nanosheet structure further comprises a plurality of spacers disposed on sides of the plurality of gate structures at least one of over and under the respective ones of the plurality of dielectric layers; and
sides of respective ones of the plurality of spacers contact the side of the at least one source/drain region.

14. The semiconductor device of claim 13, wherein the sides of the respective ones of the plurality of spacers are coplanar with the sides of the respective ones of the plurality of two-dimensional semiconductor material layers.

15. The semiconductor device of claim 13, wherein the sides of the respective ones of the plurality of spacers are coplanar with the sides of the respective ones of the plurality of dielectric layers.

16. The semiconductor device of claim 10, wherein the respective ones of the plurality of two-dimensional semiconductor material layers are thinner than respective ones of the plurality of dielectric layers.

17. The semiconductor device of claim 10, wherein respective ones of the plurality of dielectric layers are wider than the respective ones of the plurality of gate structures.

18. A semiconductor device comprising:
a nanosheet structure comprising:
a plurality of gate structures alternately stacked with a plurality of dielectric layers; and
a plurality of spacers disposed on sides of the plurality of gate structures at least one of over and under respective ones of the plurality of dielectric layers; and
at least one source/drain region disposed on a side of the nanosheet structure;
wherein sides of the respective ones of the plurality of dielectric layers contact a side of the at least one source/drain region; and
wherein sides of respective ones of the plurality of spacers contact the side of the at least one source/drain region and are coplanar with the sides of the respective ones of the plurality of dielectric layers.

19. The semiconductor device of claim 18, wherein:
the nanosheet structure further comprises a plurality of two-dimensional semiconductor material layers; and
respective ones of the plurality of two-dimensional semiconductor material layers are disposed between adjacent ones of the plurality of gate structures and the plurality of dielectric layers.

20. The semiconductor device of claim 19, wherein a gate dielectric layer of respective ones of the plurality of gate structures contacts at least one of the plurality of two-dimensional semiconductor material layers.
